(19) United States
(12) Patent Application Publication
(10) Pub. No.: US 2006/0081919 A1
(43) Pub. Date: Apr. 20, 2006

(54) Semiconductor device

(75) Inventors: Tomoki Inoue, Tokyo (JP); Hideaki Ninomiya, Kanagawa (JP); Koichi Sugiyama, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/044,065

(22) Filed: Jan. 28, 2005

(30) Foreign Application Priority Data
Oct. 20, 2004 (JP) 2004-305746

(51) Int. Cl. H01L 29/24

(52) U.S. Cl. 257/330

(57) ABSTRACT

A semiconductor device comprising: a first-conductivity-type base layer; a second-conductivity-type emitter layer formed on a first main surface of said first-conductivity-type base layer; a collector electrode formed in contact with a surface of said second-conductivity-type emitter layer; a second-conductivity-type base layer formed on a second main surface of said first-conductivity-type base layer; a plurality of trenches which extend through said second-conductivity-type base layer to reach a predetermined depth of said first-conductivity-type base layer, and has a longitudinal direction in one direction; a gate electrode formed in said trench via a gate insulating film; a first-conductivity-type emitter layer selectively formed in contact with side walls of said trench, in a surface portion of said second-conductivity-type base layer; an emitter electrode formed in contact with a surface of said second-conductivity-type base layer and a surface of said first-conductivity-type emitter layer; and a second-conductivity-type semiconductor layer selectively formed in a region along the longitudinal direction of said trench, near the surface of said first-conductivity-type emitter layer.

### CROSS REFERENCE TO RELATED APPLICATION

This application is based upon and claims benefit of priority under 35 USC §119 from the Japanese Patent Application No. 2004-305746, filed on Oct. 20, 2004, the entire contents of which are incorporated herein by reference.

### BACKGROUND OF THE INVENTION

The present invention relates to a power semiconductor switching device and, more particularly, to a MOS semiconductor device which realizes a high short-circuit breakdown capability.

Recently, an IGBT (Insulated Gate Bipolar Transistor) is widely used as a power semiconductor device having a breakdown capability of 600 V or more.

The IGBT has an input impedance higher than that of a BJT (Bipolar Junction Transistor) or GTO (Gate Turn Off) thyristor used as a semiconductor switch. This simplifies not only the configuration of a gate circuit but also a protective circuit because the short-circuit breakdown capability is high.

The operation of the conventional IGBT will be explained below.

When a bias voltage which is positive with respect to an emitter electrode is applied to a gate electrode, an inversion layer is formed on the surface of a p-type base layer, and electrons are injected into an n⁻-type base layer. Consequently, because a p⁺-type collector layer is biased positively with respect to the n⁻-type base layer, holes are injected from the p⁺-type collector layer into the n⁻-type base layer to turn on the transistor.

In this state, an electric current flows from the emitter electrode into the inversion layer through an n⁺-type emitter layer. Since a resistance is present between the n⁺-type emitter electrode and inversion layer, the voltage of the n⁺-type emitter layer rises. As a consequence, the surface potential of the n-type base layer rises, so the inversion layer formed on the surface of the p-type base layer pinches off, and the MOSFET readily saturates.

Accordingly, the saturation current of the IGBT reduces, and the short-circuit breakdown capability increases.

In the IGBT having a trench gate, however, the impurity concentration on the surface of the n⁺-type emitter layer must be set to a predetermined value or more, in order to improve the electrical contact between the emitter electrode and n⁺-type emitter layer.

On the other hand, since the n⁺-type emitter layer must be fine, the pattern width of the n⁺-type emitter layer is difficult to control. This makes it difficult to control the resistance between the emitter electrode and inversion layer.

As described above, in the fine trench type IGBT, it is difficult to suppress the saturation current by appropriately controlling the resistance value between the emitter electrode and inversion layer, thereby increasing the short-circuit breakdown capability.

References disclosing the conventional IGBTs are as follows.
1: WO99/38214
2: Japanese Patent Laid-Open No. 9-283755
3: Japanese Patent Laid-Open No. 2003-17699
4: U.S. Pat. No. 6,072,214

### SUMMARY OF THE INVENTION

According to one aspect of the present invention, there is provided a semiconductor device comprising:

a first-conductivity-type base layer;

a second-conductivity-type emitter layer formed on a first main surface of said first-conductivity-type base layer;

a collector electrode formed in contact with a surface of said second-conductivity-type emitter layer;

a second-conductivity-type base layer formed on a second main surface of said first-conductivity-type base layer;

a plurality of trenches which extend through said second-conductivity-type base layer to reach a predetermined depth of said first-conductivity-type base layer, and has a longitudinal direction in one direction;

a gate electrode formed in said trench via a gate insulating film;

a first-conductivity-type emitter layer selectively formed in contact with side walls of said trench, in a surface portion of said second-conductivity-type base layer;

an emitter electrode formed in contact with a surface of said second-conductivity-type base layer and a surface of said first-conductivity-type emitter layer; and

a second-conductivity-type semiconductor layer selectively formed in a region along the longitudinal direction of said trench, near the surface of said first-conductivity-type emitter layer.

According to one aspect of the present invention, there is provided a semiconductor device comprising:

a first-conductivity-type base layer;

a second-conductivity-type emitter layer formed on a first main surface of said first-conductivity-type base layer;

a collector electrode formed in contact with a surface of said second-conductivity-type emitter layer;

a second-conductivity-type base layer formed on a second main surface of said first-conductivity-type base layer;

a plurality of trenches which extend through said second-conductivity-type base layer to reach a predetermined depth of said first-conductivity-type base layer;

a gate electrode formed in said trench via a gate insulating film;

a first-conductivity-type emitter layer selectively formed in contact with side walls of said trench, in a surface portion of said second-conductivity-type base layer;

an emitter electrode formed in contact with a surface of said second-conductivity-type base layer and a surface of said first-conductivity-type emitter layer; and

a second-conductivity-type semiconductor layer selectively formed in a region along a longitudinal direction of said trench, near the surface of said first-conductivity-type emitter layer,

wherein said trenches are formed into a mesh-like shape, and said gate electrode is formed into a mesh-like shape in said trench via said gate insulating film, and

in each region surrounded by said trenches,

said first-conductivity-type emitter layer is selectively formed along the side walls of said trench, in the surface portion of said second-conductivity-type base layer,

said emitter electrode is formed in contact with the surface of said second-conductivity-type base layer and the surface of said first-conductivity-type emitter layer, and

said second-conductivity-type semiconductor layer is selectively formed along the side walls of said trench, near the surface of said first-conductivity-type emitter layer.

According to one aspect of the present invention, there is provided a semiconductor device comprising:
a first-conductivity-type base layer;
a second-conductivity-type emitter layer formed on a first main surface of said first-conductivity-type base layer;
a collector electrode formed in contact with a surface of said second-conductivity-type emitter layer;
a second-conductivity-type base layer formed on a second main surface of said first-conductivity-type base layer;
a plurality of trenches which extend through said second-conductivity-type base layer to reach a predetermined depth of said first-conductivity-type base layer;
a gate electrode formed in said trench via a gate insulating film;
a first-conductivity-type emitter layer selectively formed in contact with side walls of said trench, in a surface portion of said second-conductivity-type base layer;
an emitter electrode formed in contact with a surface of said second-conductivity-type base layer and a surface of said first-conductivity-type emitter layer; and

a second-conductivity-type semiconductor layer selectively formed in a region along a longitudinal direction of said trench, near the surface of said first-conductivity-type emitter layer,

wherein said plurality of trenches are formed into an annular shape, and said gate electrode is buried in said trench via said gate insulating film, and

in each region surrounded by said annular trenches,

said first-conductivity-type emitter layer is selectively formed along the side walls of said trench, in the surface portion of said second-conductivity-type base layer,

said emitter electrode is formed in contact with the surface of said second-conductivity-type base layer and the surface of said first-conductivity-type emitter layer, and

said second-conductivity-type semiconductor layer is selectively formed along the side walls of said trench, near the surface of said first-conductivity-type emitter layer.

### BRIEF DESCRIPTION OF THE DRAWINGS

FIG. 1 is a plan view showing the planar arrangement of a semiconductor device according to the first embodiment of the present invention;

FIG. 2 is a sectional view showing a longitudinal section taken along a line B1-B1 in FIG. 1;

FIG. 3 is a sectional view showing a longitudinal section taken along a line A1-A1 in FIG. 1;

FIG. 4 is a sectional view showing the longitudinal section of a semiconductor device according to the first modification of the first embodiment of the present invention;

FIG. 5 is a sectional view showing the longitudinal section of the semiconductor device according to the first modification of the first embodiment;

FIG. 6 is a plan view showing the planar arrangement of a semiconductor device according to the second modification of the first embodiment of the present invention;

FIG. 7 is a sectional view showing a longitudinal section taken along a line B2-B2 in FIG. 6;

FIG. 8 is a sectional view showing a longitudinal section taken along a line A2-A2 in FIG. 6;

FIG. 9 is a graph showing the influence which an area ratio b/a of a region a to a region b has on a saturation current in the second modification of the first embodiment;

FIG. 10 is a plan view showing the planar arrangement of a semiconductor device according to the second embodiment of the present invention;

FIG. 11 is a sectional view showing a longitudinal section taken along a line B3-B3 in FIG. 10;

FIG. 12 is a sectional view showing a longitudinal section taken along a line A3-A3 in FIG. 10;

FIG. 13 is a sectional view showing the longitudinal section of a semiconductor device according to the third embodiment of the present invention;

FIG. 14 is a sectional view showing a longitudinal section taken along a line B4-B4 in FIG. 13;

FIG. 15 is a sectional view showing a longitudinal section taken along a line A4-A4 in FIG. 13;

FIG. 16 is a sectional view showing the longitudinal section of a semiconductor device according to the first modification of the third embodiment of the present invention;

FIG. 17 is a plan view showing the planar arrangement of a semiconductor device according to the fourth embodiment of the present invention;

FIG. 18 is a sectional view showing a longitudinal section taken along a line B5-B5 in FIG. 17;

FIG. 19 is a sectional view showing a longitudinal section taken along a line A5-A5 in FIG. 17;

FIG. 20 is a sectional view showing the longitudinal section of a semiconductor device according to the first modification of the fourth embodiment of the present invention;

FIG. 21 is a sectional view showing the longitudinal section of a semiconductor device according to the second modification of the fourth embodiment of the present invention;

FIG. 22 is a sectional view showing a longitudinal section taken along a line A6-A6 in FIG. 21;

FIG. 23 is a sectional view showing the longitudinal section of a semiconductor device according to the third modification of the fourth embodiment of the present invention;

FIG. 24 is a sectional view showing a longitudinal section taken along a line A7-A7 in FIG. 23;

FIG. 25 is a plan view showing the planar arrangement of a semiconductor device according to the fifth embodiment of the present invention;

FIG. 26 is a sectional view showing a longitudinal section taken along a line A8-A8 in FIG. 25;

FIG. 27 is a plan view showing the planar arrangement of a semiconductor device according to the first modification of the fifth embodiment of the present invention;

FIG. 28 is a plan view showing the planar arrangement of a semiconductor device according to the sixth embodiment of the present invention;

FIG. 29 is a sectional view showing a longitudinal section taken along a line A9-A9 in FIG. 28;

FIG. 30 is a sectional view showing the longitudinal section of a semiconductor device according to the first modification of the sixth embodiment of the present invention;

FIG. 31 is a plan view showing the planar arrangement of a semiconductor device according to the seventh embodiment of the present invention;

FIG. 32 is a sectional view showing a longitudinal section taken along a line A10-A10 in FIG. 31;

FIG. 33 is a plan view showing the planar arrangement of a semiconductor device according to the first modification of the seventh embodiment of the present invention;

FIG. 34 is a plan view showing the planar arrangement of a semiconductor device according to the eight embodiment of the present invention;

FIG. 35 is a sectional view showing a longitudinal section taken along a line A11-A11 in FIG. 30.

### DETAILED DESCRIPTION OF THE INVENTION

Embodiments of the present invention will be described below with reference to the accompanying drawings.

Note that in the following explanation, the first conductivity type is n-type, and the second conductivity type is p-type. However, the combination of the conductivity types is not limited to this one; the first and second conductivity types may also be p- and n-types, respectively.

Note also that the same reference numerals denote constituent elements having substantially the same functions or arrangements, and a repetitive explanation thereof will be omitted.

### FIRST EMBODIMENT

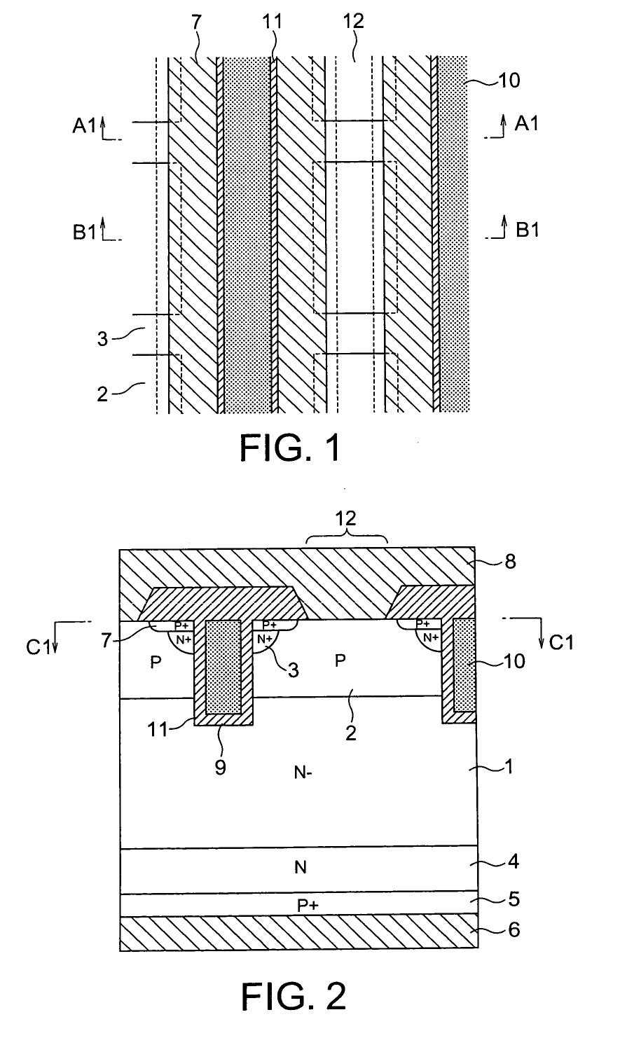

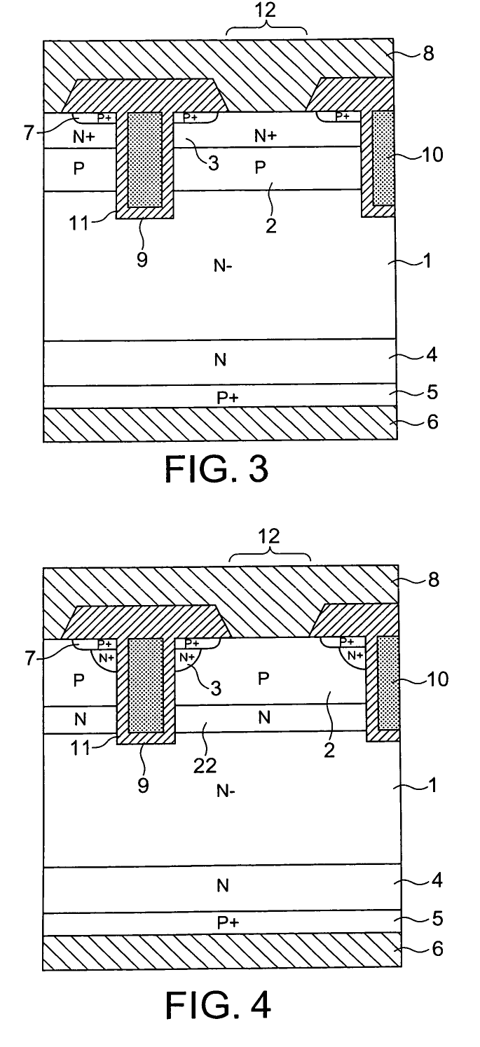

FIG. 1 shows a plan view of an IGBT according to the first embodiment of the present invention. FIG. 2 shows a longitudinal section taken along a line B1-B1 in FIG. 1. FIG. 3 shows a longitudinal section taken along a line A1-A1 in FIG. 1. The plan view of FIG. 1 corresponds to a cross section taken along a line C1-C1 in FIG. 2.

A p⁺-type emitter layer 5 is formed on one surface of an n⁻-type base layer 1 via an n-type buffer layer 4, and a collector electrode 6 is formed on the surface of the p⁺-type emitter layer 5.

A p-type base layer 2 is formed on the other surface of the n⁻-type base layer 1. Trenches 9 extend to a predetermined depth of the n⁻-type base layer 1 through the p-type base layer 2. A gate electrode 10 is formed in each trench 9 via a gate oxide film 11.

In a region separated by the trenches 9, a contact portion 12 is formed on the surface of the p-type base layer 2 and electrically connected to an emitter electrode 8.

In the surface portion of the p-type base layer 2, n⁺-type emitter layers 3 are formed on the two sides of the trench 9 so as to oppose each other along the longitudinal direction of the trench 9. P⁺-type limiting layers 7 cover the surfaces of those portions of the n⁺-type emitter layers 3, which extend along the longitudinal direction of the trench 9.

The IGBT according to this embodiment operates as follows.

When a bias voltage which is positive with respect to the emitter electrode 8 is applied to the gate electrode 10, an inversion layer is formed on the surface of the p-type base layer 2, and electrons are injected into the n⁻-type base layer 1.

Consequently, since the p⁺-type emitter layer 5 is biased positively with respect to the n⁻-type base layer 1, and holes are injected from the p⁺-type emitter layer 5 into the n⁻-type base layer 1 to turn on the device.

In this embodiment, the p⁺-type limiting layers 7 are formed on the surfaces of those portions of the n⁺-type emitter layers 3, which extend along the longitudinal direction of the trench 9, thereby removing those portions of the n⁺-type emitter layers 3, in which the impurity concentration is high. This increases the sheet resistance of the n⁺-type emitter layers 3.

When the density of an electric current which flows through the n⁺-type emitter layers 3 increases upon short-circuit, the potential of those portions of the n⁺-type emitter layers 3, which connect to the inversion layer formed on the surface of the p-type base layer 2 rises. Accordingly, the inversion layer formed on the surface of the p-type base layer 2 pinches off, and the MOSFET readily saturates.

As a consequence, this embodiment reduces the saturation current and increases the short-circuit breakdown capability.

### First Modification of First Embodiment

The first modification of the first embodiment is equivalent to modifying the longitudinal section taken along the line B1-B1 in FIG. 1 into a structure shown in FIG. 4, and modifying the longitudinal section taken along the line A1-A1 in FIG. 1 into a structure shown in FIG. 5.

That is, the first modification has a structure in which in a region sandwiched between trenches 9, an n-type barrier layer 22 is formed between a p-type base layer 2 and n⁻-type base layer 1.

Similar to the first embodiment described above, the first modification can also increase the short-circuit breakdown capability since p⁺-type limiting layers 7 are formed.

An IGBT differs from a MOSFET in that when the transistor is ON, carriers build up in an n⁻-type base layer and decrease the resistance, thereby causing conductivity modulation. It is, therefore, possible by forming the n-type barrier layer 22 to increase the amount of carriers which build up in the n⁻-type base layer 1, and decrease the ON-state voltage.

When the p⁺-type limiting layers 7 are formed to suppress the saturation current and increase the sheet resistance of n⁺-type emitter layers 3, the ON-state voltage drop slightly increases. In the first modification, however, the ON-state voltage can be decreased by the n-type barrier layer 22. That is, the first modification can suppress the rise of the ON-state voltage, and increase the short-circuit breakdown capability.

### Second Modification of First Embodiment

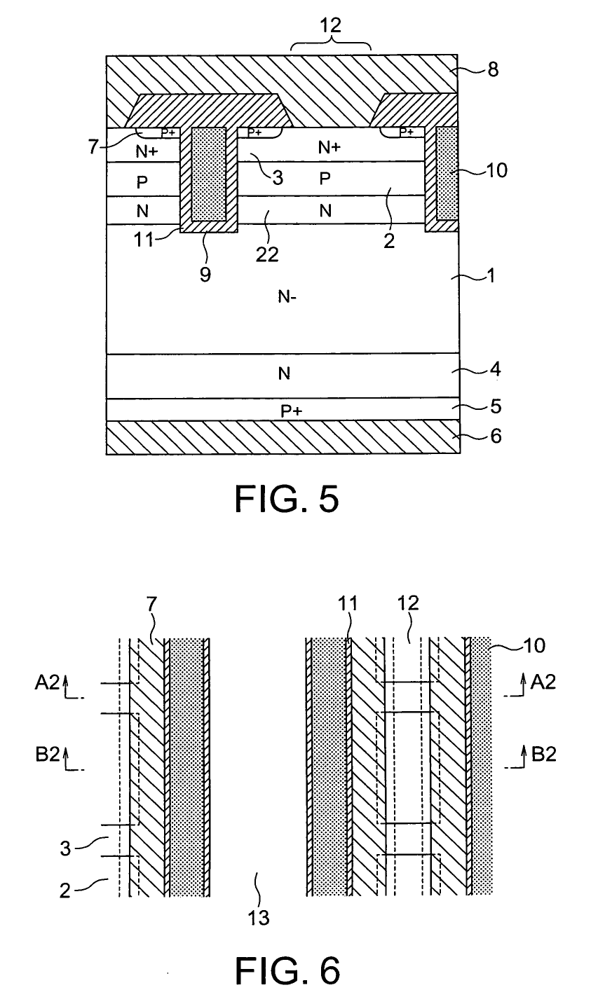

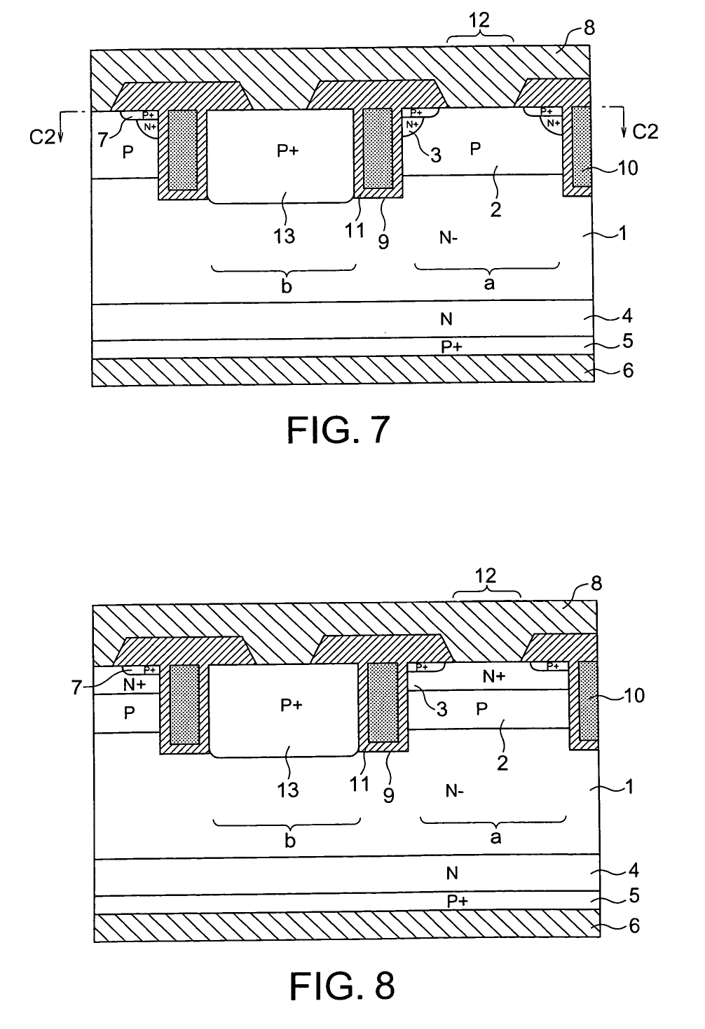

FIG. 6 shows the planar structure of an IGBT according to the second modification of the first embodiment of the present invention. FIG. 7 shows a longitudinal section taken along a line B2-B2 in FIG. 6. FIG. 8 shows a longitudinal section taken along a line A2-A2 in FIG. 6. The plan view of FIG. 6 corresponds to a cross section taken along a line C2-C2 in FIG. 7.

This IGBT according to the second modification is characterized in that a region between trenches 9 is divided into a region a as a current flow path and another region b.

In the region a, a p-type base layer 2 and n⁺-type emitter layers 3 are formed. In the region b, a p⁺-type dummy layer 13 is formed to substantially occupy the region b.

As described above, an IGBT differs from a MOSFET in that when the transistor is ON, carriers build up in an n⁻-type base layer and decrease the resistance, thereby causing conductivity modulation.

In the second modification, therefore, the area ratio of the region a to the region b in a plane is appropriately set. This reduces the rise of the ON-state voltage caused by a reduction of the current flow path by decreasing the ON-state voltage by increasing the amount of carriers which build up in the n⁻-type base layer 2.

Accordingly, it is possible to decrease the channel density without raising the ON-state voltage, and reduce the saturation current.

In this state, the density of an electric current which flows through the n⁺-type emitter layers 3 increases. Since p⁺-type limiting layers 7 are formed, the sheet resistance of the n⁺-type emitter layers 3 increases, so the saturation current can be more effectively suppressed. As a consequence, the second modification can increase the short-circuit breakdown capability.

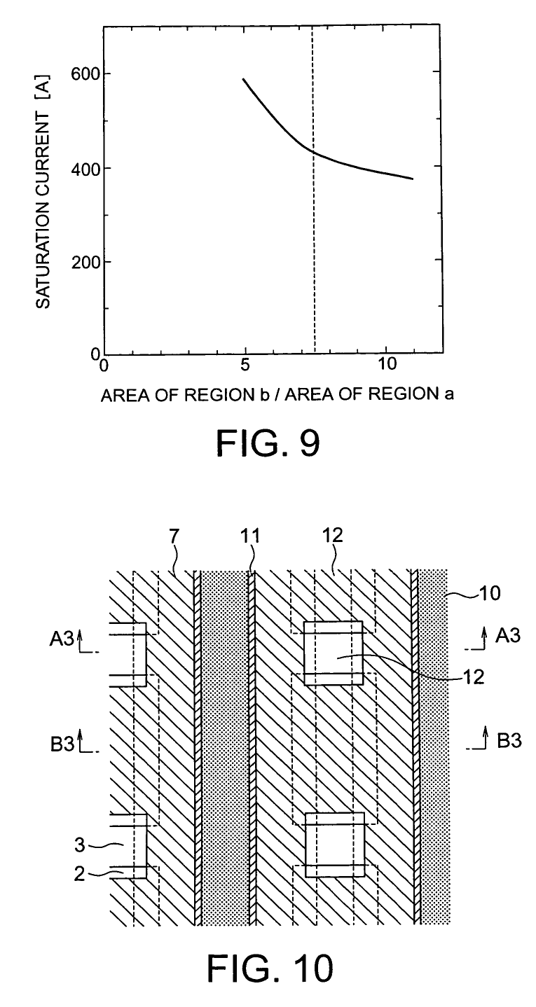

FIG. 9 shows the relationship between the area ratio b/a of the region b to the region a and the saturation current. If the area ratio b/a is lower than 7.5, the saturation current abruptly reduces as the area ratio b/a increases. However, if the area ratio b/a is higher than 7.5, the reduction ratio of the saturation current decreases.

Accordingly, the area ratio b/a of the region b to the region a is desirably 7.5 or more.

The second modification can suppress the rise of the ON-state voltage and increase the short-circuit breakdown capability at the same time.

### SECOND EMBODIMENT

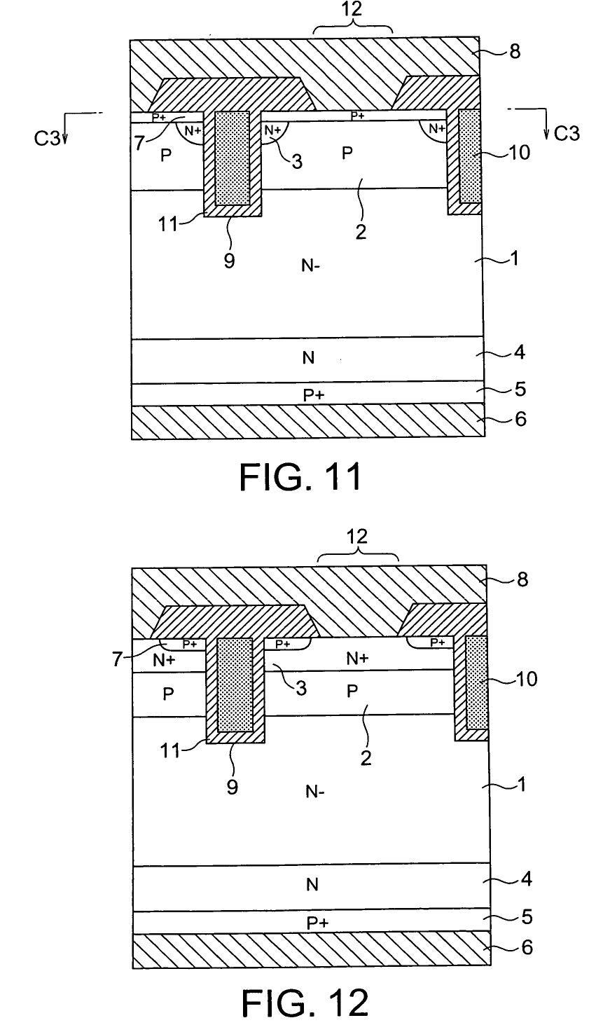

FIG. 10 shows the planar structure of an IGBT according to the second embodiment of the present invention. FIG. 11 shows a longitudinal section taken along a line B3-B3 in FIG. 10. FIG. 12 shows a longitudinal section taken along a line A3-A3 in FIG. 10. The plan view of FIG. 10 corresponds to a cross section taken along a line C3-C3 in FIG. 11.

The IGBT according to this embodiment differs from the IGBT of the first embodiment described above in that as shown in FIG. 10, a p⁺-type limiting layer 7 is formed on the entire surface of a semiconductor substrate except for a contact portion in which n⁺-type emitter layers 3 come in contact with an emitter electrode 8.

To improve the electrical contact between a p-type base layer 2 having a low impurity concentration and the emitter electrode 8, a p⁺-type contact layer is usually formed on the surface of the p-type base layer 2. In this embodiment, the p⁺-type limiting layer 7 can also have the function of this p⁺-type contact layer. This makes it possible to reduce the fabrication process steps and reduce the fabrication cost.

In this embodiment, as in the first embodiment, it is possible by forming the p⁺-type limiting layer 7 to limit the saturation current of the IGBT, and increase the short-circuit breakdown capability.

### THIRD EMBODIMENT

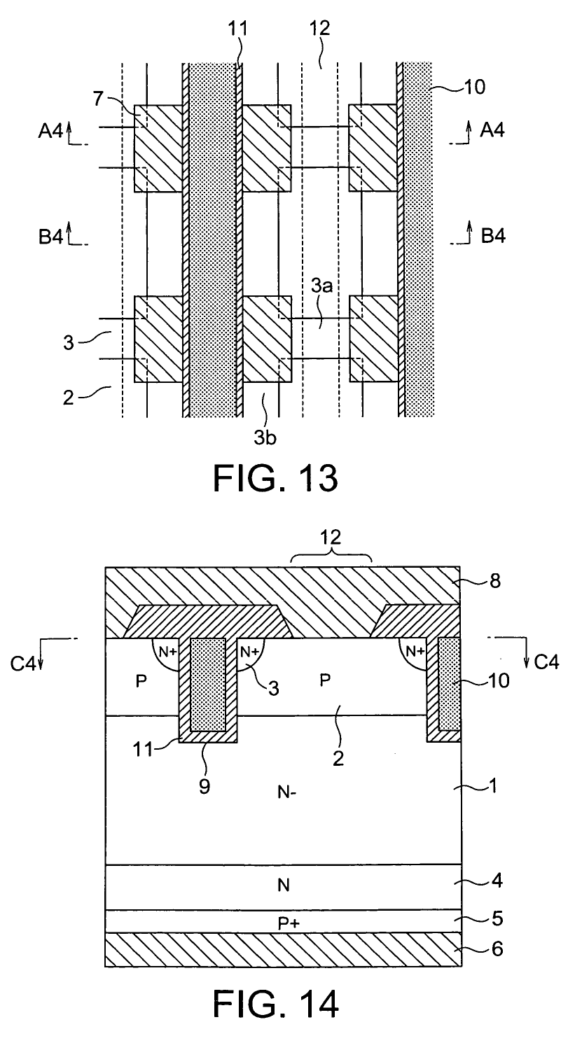

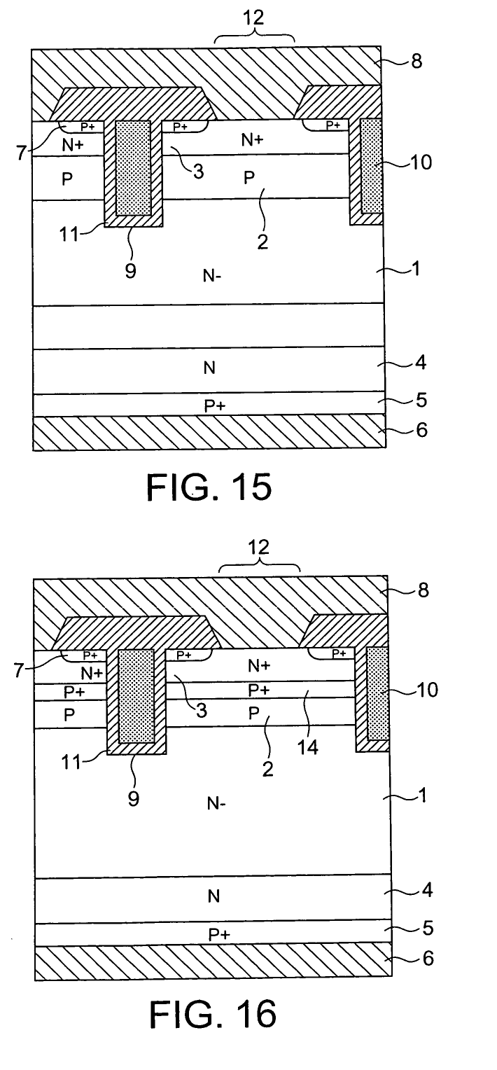

FIG. 13 shows the planar arrangement of an IGBT according to the third embodiment of the present invention. FIG. 14 shows a longitudinal section taken along a line B4-B4 in FIG. 13. FIG. 15 shows a longitudinal section taken along a line A4-A4 in FIG. 13. The plan view of FIG. 13 corresponds to a cross section taken along a line C4-C4 in FIG. 14.

The IGBT of this embodiment is characterized in that a p⁺-type limiting layer 7 is formed only on the surface of each intersection between portions 3a and 3b of an n⁺-type emitter layer 3. The portion 3a is formed perpendicularly to the longitudinal direction of a trench 9 in order to obtain a contact with an emitter electrode 8. The portion 3b is formed along the longitudinal direction of the trench 9.

In this embodiment, the formation area of the p⁺-type limiting layer 7 is smaller than that in the first embodiment. This decreases the increase in sheet resistance of the n⁺-type emitter layer 3.

An electron current, however, concentrates to the intersection of the portions 3a and 3b of the n⁺-type emitter layer 3. Accordingly, the short-circuit breakdown capability can be increased by forming the p⁺-type limiting layer 7 in this intersection and increasing the sheet resistance of the n⁺-type emitter layer 3 to a desired value.

This embodiment is particularly useful in an IGBT having a relatively low rated voltage, in which the arrangements as described in the first and second modifications of the first embodiment cannot be used.

### Modification of Third Embodiment

As shown in FIG. 16, the first modification of the third embodiment of the present invention further has a p⁺-type semiconductor layer 14 immediately below a portion 3a, which is formed perpendicularly to the longitudinal direction of a trench 9, of an n⁺-type emitter layer 3, in addition to the arrangement of the third embodiment described above.

With this arrangement, at the intersection of the portion 3a and a portion 3b, a p⁺-type limiting layer 7 is formed in the upper portion of the n⁺-type emitter layer 3, and the p⁺-type semiconductor layer 14 is formed in the lower portion of the n⁺-type emitter layer 3. This facilitates controlling the sheet resistance of the n⁺-type emitter layer 3 in this intersection.

Furthermore, the p⁺-type semiconductor layer 14 allows a hole current, which flows when the IGBT is turned off, to easily flow through an emitter electrode 8. This prevents destruction by latch-up.

### FOURTH EMBODIMENT

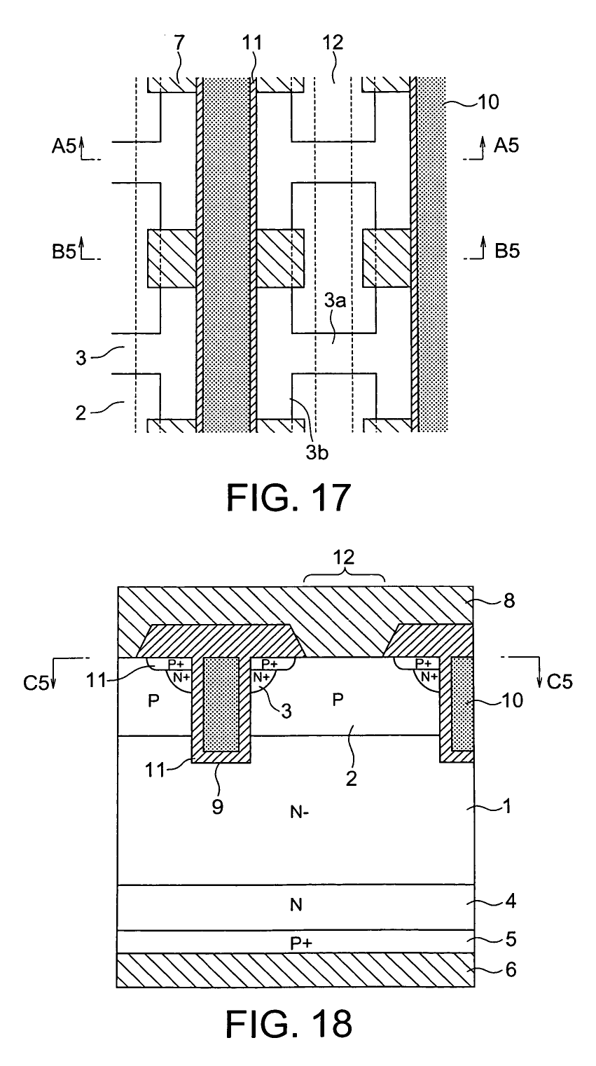

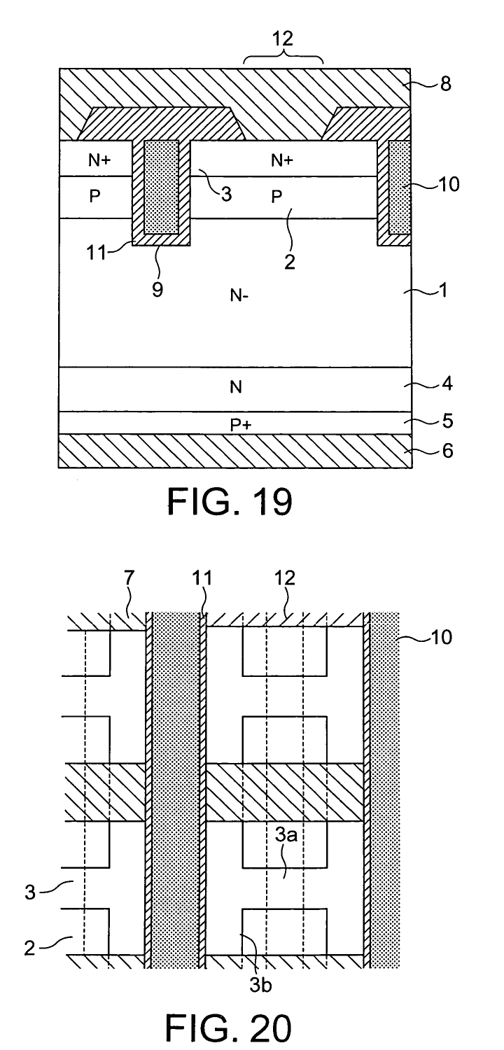

FIG. 17 shows the planar arrangement of an IGBT according to the fourth embodiment of the present invention. FIG. 18 shows a longitudinal section taken along a line B5-B5 in FIG. 17. FIG. 19 shows a longitudinal section taken along a line A5-A5 in FIG. 17. The plan view of FIG. 17 corresponds to a cross section taken along a line C5-C5 in FIG. 18.

An n⁺-type emitter layer 3 has a portion 3b formed along the longitudinal direction of a trench 9, and a portion 3a formed in a direction perpendicular to this longitudinal direction. The IGBT of this embodiment is characterized in that a p⁺-type limiting layer 7 is formed only on the surface of a substantially central portion of the portion 3b, which is positioned between the intersections of the portions 3a and 3b.

When the p⁺-type limiting layer 7 is formed on the surface of the intersection of the portions 3a and 3b of the n⁺-type emitter layer 3 as in the third embodiment shown in FIG. 13, the sheet resistance of the intersection to which almost all electron currents concentrate rises. As a consequence, an action of suppressing the saturation current occurs and the ON-state voltage rises even in a normal operation state in which the current density is relatively low.

By contrast, in the IGBT of this embodiment, the p⁺-type limiting layer 7 is formed on the surface of that portion of the n⁺-type emitter layer 3, in which only some electron currents flow. Accordingly, the rise of the ON-state voltage in a normal operation state can be suppressed. On the other hand, in a short-circuit state in which the current density is high, an action of suppressing the saturation current occurs, so the short-circuit breakdown capability can be increased. Although this suppressing action is inferior to that of the third embodiment, this embodiment has an action of suppressing the rise of the ON-state voltage in a normal operation state. Therefore, a desirable one of these actions need only be applied in accordance with the priorities of the short-circuit breakdown capability and ON-state voltage.

### First Modification of Fourth Embodiment

As shown in FIG. 20, the first modification of the fourth embodiment is characterized in that a p⁺-type limiting layer 7 is formed into a stripe, in a direction perpendicular to the longitudinal direction of a trench 9, in a substantially central portion between portions 3a of n⁺-type emitter layers 3.

To improve the electrical contact between a p-type base layer 2 and emitter electrode 8, a p⁺-type contact layer is usually formed on the surface of the p-type base layer 2. In this embodiment, the p⁺-type limiting layer 7 can be given this function of the p⁺-type contact layer. This makes it possible to shorten the fabrication process and reduce the fabrication cost.

In addition, no mask alignment need be performed between the mask pattern of the p⁺-type contact layer and the mask pattern of the p⁺-type limiting layer 7. This prevents variations in element characteristics caused by misalignment, and thereby makes the element characteristics stable.

### Second Modification of Fourth Embodiment

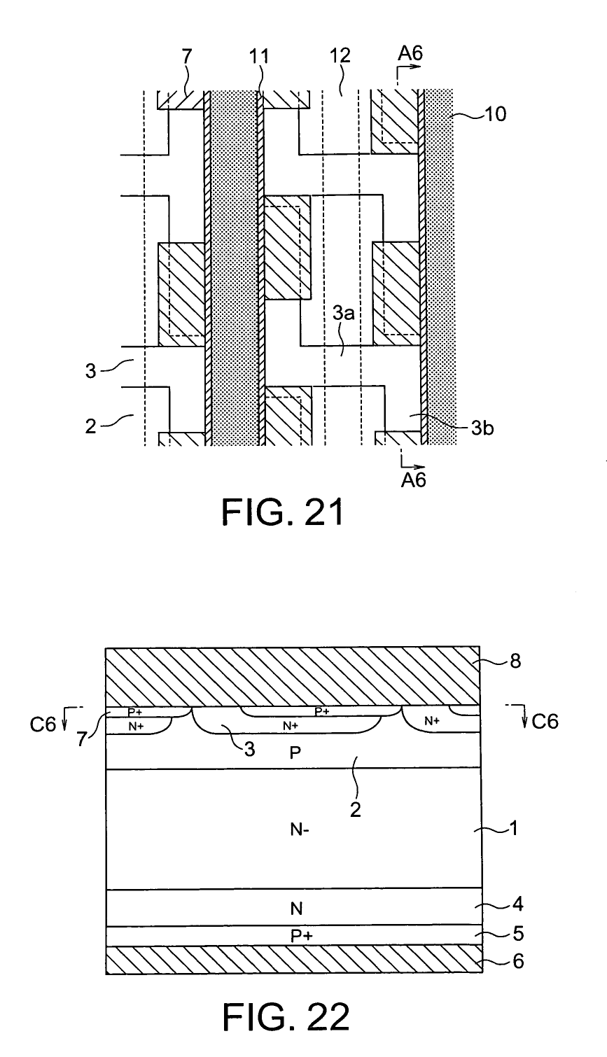

The second modification of the fourth embodiment of the present invention is characterized in that n⁺-type emitter layers 3 have a pattern as shown in FIG. 21. FIG. 22 shows a longitudinal section taken along a line A6-A6 in FIG. 21. The plan view of FIG. 21 corresponds to a cross section taken along a line C6-C6 in FIG. 22.

As shown in FIGS. 21 and 22, a portion 3b of the n⁺-type emitter layer 3, which is formed along the longitudinal direction of a trench 9 does not evenly extend. That is, portions 3b adjacent to each other are separated in a region perpendicular to a portion 3a which is perpendicular to the longitudinal direction of the trench 9.

In this arrangement of the second modification, the n⁺-type emitter layers 3 extend only in one direction along the longitudinal direction of the trench 9. This makes the electron current density in the portion 3b relatively high.

In addition, a p⁺-type limiting layer 7 is present in a position separated from the portion 3a, in which a contact with an emitter electrode 8 is present, of the n⁺-type emitter layer 3.

Accordingly, the second modification can improve the effect of suppressing the saturation current, and increase the short-circuit breakdown capability.

### Third Modification of Fourth Embodiment

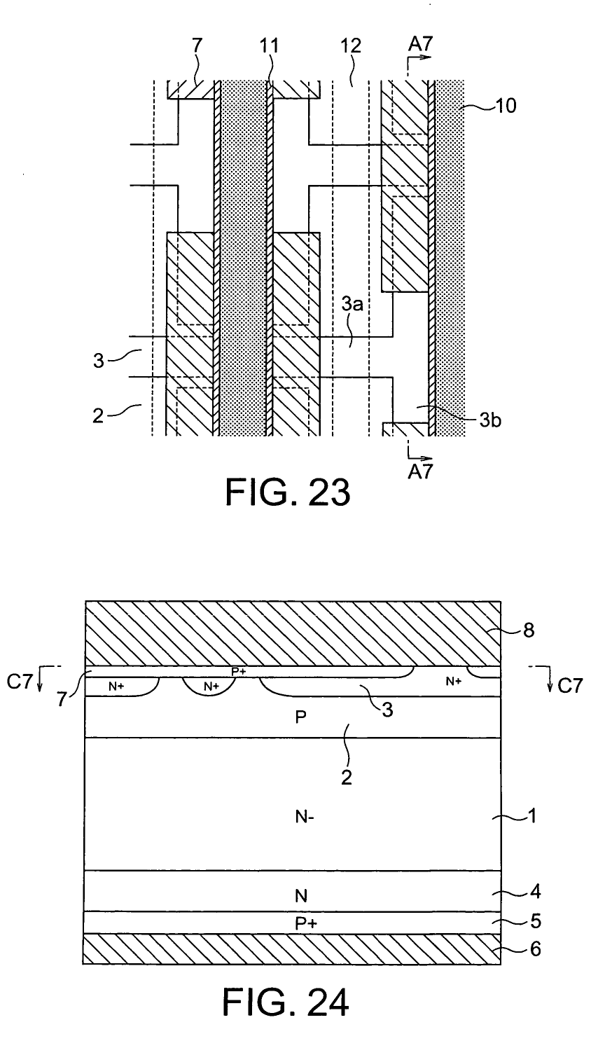

The third modification of the fourth embodiment of the present invention is characterized in that n⁺-type emitter layers 3 have a pattern as shown in FIG. 23. FIG. 24 shows a longitudinal section taken along a line A7-A7 in FIG. 23. The plan view of FIG. 23 corresponds to a cross section taken along a line C7-C7 in FIG. 24.

As shown in FIGS. 23 and 24, a portion 3a of the n⁺-type emitter layer 3, which is perpendicular to the longitudinal direction of a trench 9 extends from a substantially central portion of a portion 3b of the n⁺-type emitter layer 3, which is formed along the longitudinal direction of the trench 9, thereby separating the n⁺-type emitter layers 3 adjacent to each other.

Since the third modification has a structure in which the n⁺-type emitter layers 3 are thus separated, the electron current density in the portion 3a of the n⁺-type emitter layer 3 is relatively high. This makes it possible to suppress the saturation current and increase the short-circuit breakdown capability.

### FIFTH EMBODIMENT

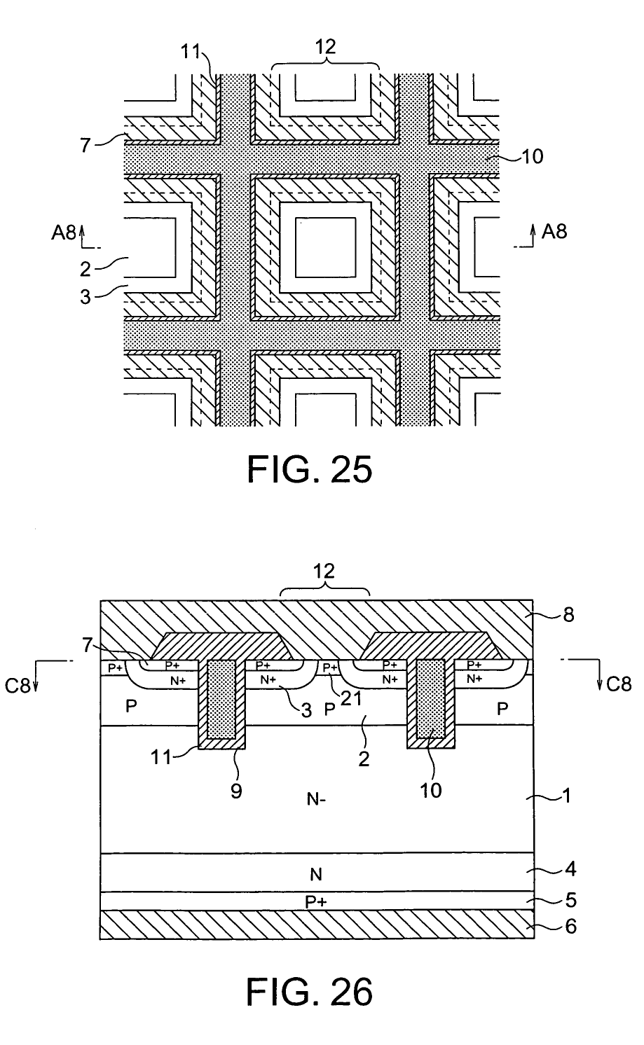

FIG. 25 shows the planar arrangement of an IGBT according to the fifth embodiment of the present invention. FIG. 26 shows a longitudinal section taken along a line A8-A8 in FIG. 25. The plan view of FIG. 25 corresponds to a cross section taken along a line C8-C8 in FIG. 26.

In the IGBT of this embodiment, gate electrodes 10 formed in trenches 9 have a mesh-like shape in order to increase the channel width of an inversion layer formed on the surface of a gate oxide film 11 of a p-type base layer 2.

In the first to fourth embodiments described above, the n⁺-type emitter layer 3 has the portion 3b extending along the trench 9, and the portion 3a for obtaining a contact with the emitter electrode 8.

By contrast, in an n⁺-type emitter layer 3 of this embodiment, a portion for obtaining a contact with an emitter electrode 8 and a portion formed along inner walls surrounded by the trenches 9 are integrated.

Also, a p⁺-type limiting layer 7 covers most of the surface of the n⁺-type emitter layer 3 except for a contact portion 12 where the n⁺-type emitter layer 3 is in contact with the emitter electrode 8.

Furthermore, in the first to fourth embodiments, the trench 9 is formed along the longitudinal direction. In this embodiment, however, to improve the contact between the p-type base layer 2 and emitter electrode 8, a p⁺-type contact layer 21 is formed in the surface portion of the p-type base layer 2 in addition to the p⁺-type limiting layer 7.

This embodiment can also suppress the saturation current and increase the short-circuit breakdown capability by increasing the sheet resistance of the n⁺-type emitter layer 3.

### First Modification of Fifth Embodiment

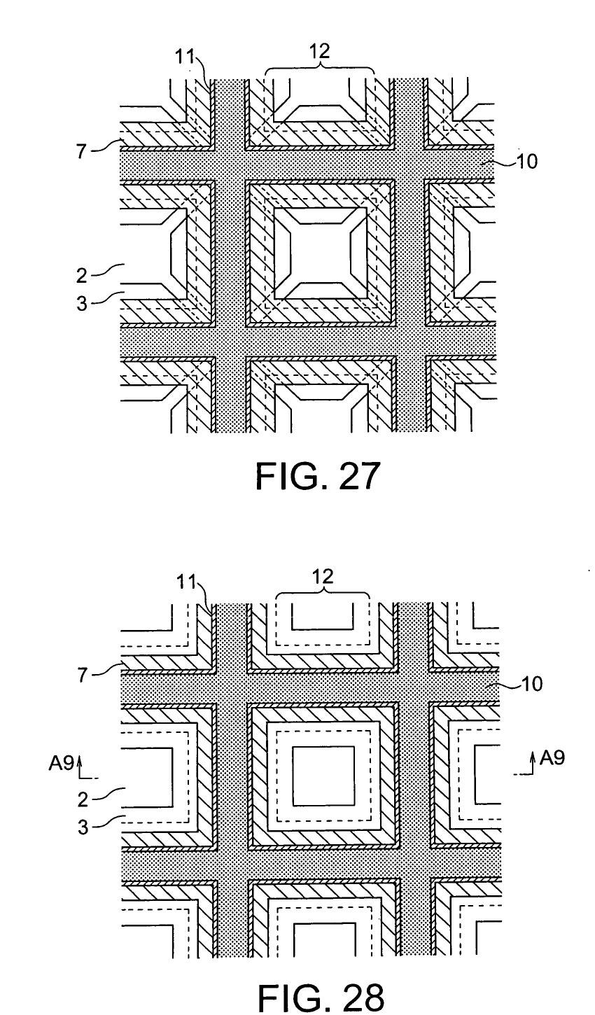

FIG. 27 shows the planar arrangement of an IGBT according to the first modification of the fifth embodiment of the present invention.

As shown in FIG. 27, the first modification is characterized in that n⁺-type emitter layers 3 are not formed in the four corners of each square region surrounded by trenches 9.

In this corner, the impurity concentration of a p-type base layer 2 normally decreases. Therefore, if a p⁺-type limiting layer 7 is formed on the surface of the corner, the threshold voltage of a MOSFET of the IGBT may decrease to vary the characteristics of the whole device.

The first modification can prevent the variations in characteristics of the whole element by preventing this decrease in threshold voltage.

### SIXTH EMBODIMENT

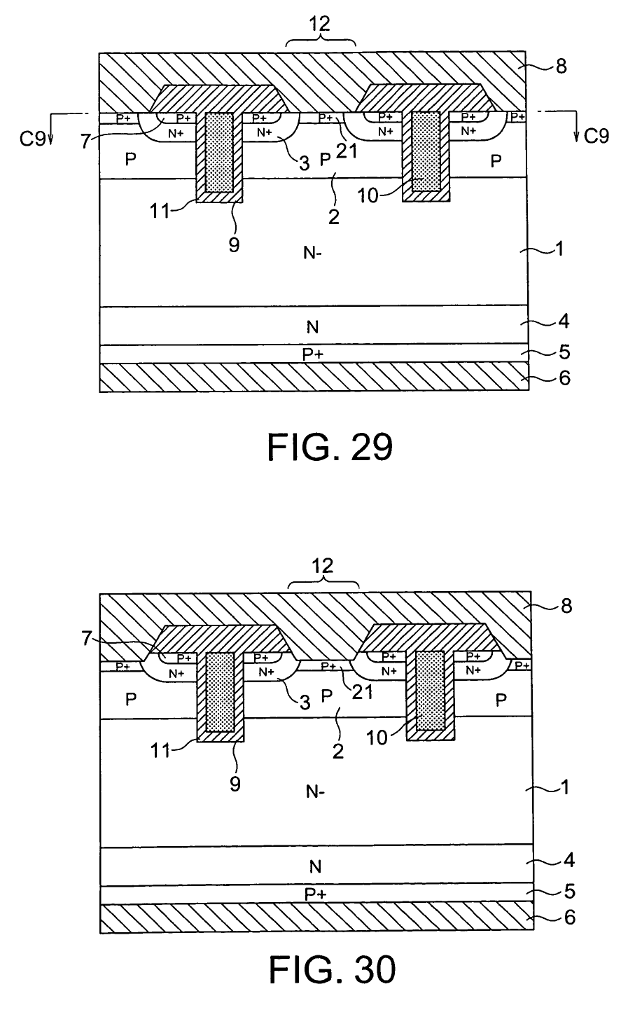

FIG. 28 shows the planar arrangement of an IGBT according to the sixth embodiment of the present invention. FIG. 29 shows a longitudinal section taken along a line A9-A9 in FIG. 28. The plan view of FIG. 28 corresponds to a cross section taken along a line C9-C9 in FIG. 29.

In the fifth embodiment shown in FIG. 26, the p⁺-type limiting layer 7 is present in the contact portion 12 where the emitter electrode 8 and n⁺-type emitter layer 3 are in contact with each other.

By contrast, the IGBT of this embodiment is characterized in that no p⁺-type limiting layer 7 is present in a contact portion 12.

This eliminates the need to take into account mask misalignment between a mask pattern for forming contact portions 12 and a mask pattern for forming p⁺-type limiting layers 7. Accordingly, these patterns can be made finer than those of the fifth embodiment.

### First Modification of Sixth Embodiment

As shown in FIG. 30 which is a longitudinal sectional view taken along a line A9-A9 in FIG. 28, in an IGBT according to the first modification of the sixth embodiment of the present invention, the substrate surface is removed into a tapered shape from a contact portion 12 where an n⁺-type emitter layer 3 and emitter electrode 8 are in contact with each other. This modification is characterized by having the contact portion 12 like this.

With this arrangement, a hole current readily flows into the emitter electrode 8 when the device is turned off, so destruction caused by latch-up can be prevented.

The first modification can also suppress the saturation current and increase the short-circuit breakdown capability by increasing the sheet resistance of the n⁺-type emitter layer 3.

### SEVENTH EMBODIMENT

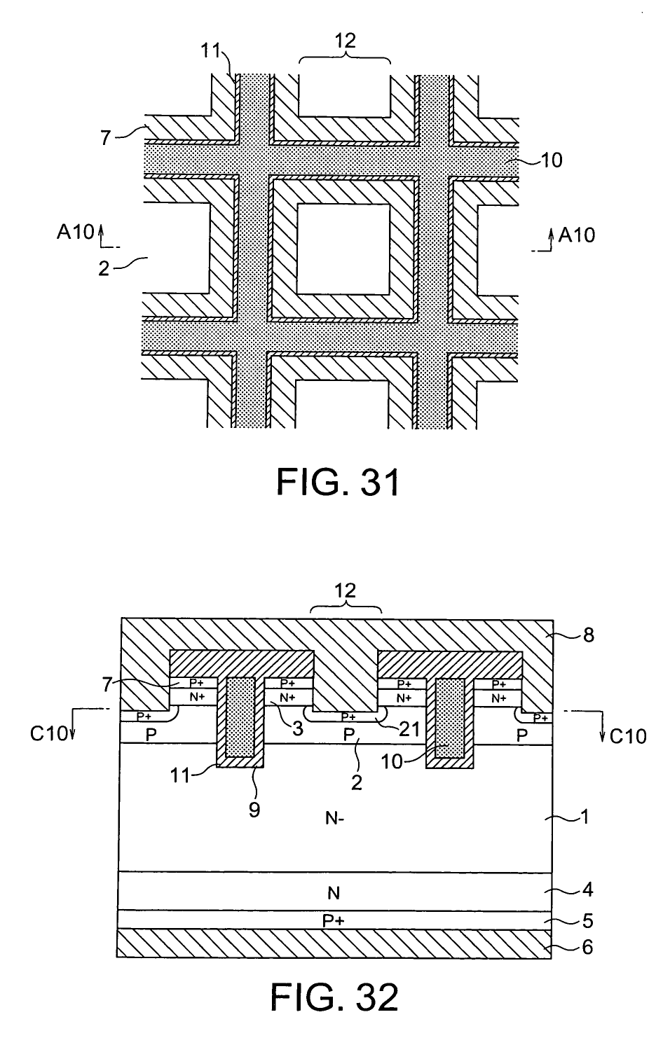

FIG. 31 shows the planar arrangement of an IGBT according to the seventh embodiment of the present invention. FIG. 32 shows a longitudinal section taken along a line A10-A10 in FIG. 31. The plan view of FIG. 31 corresponds to a cross section taken along a line C10-C10 in FIG. 32.

This IGBT of the seventh embodiment differs from the IGBT of the sixth embodiment described above in that trench-type contact portions 12 are deeper than n⁺-type emitter layers 3 and reach a p-type base layer 2.

With this arrangement, a hole current readily flows into an emitter electrode 8 when the device is turned off, so destruction caused by latch-up can be prevented.

In addition, no mask alignment is necessary when the n⁺-type emitter layers 3, p⁺-type limiting layers 7, trenches 9, and the contact portions 12 are patterned. Therefore, variations in element characteristics can be prevented.

This embodiment can also suppress the saturation current and increase the short-circuit breakdown capability by increasing the sheet resistance of the n⁺-type emitter layer 3.

### First Modification of Seventh Embodiment

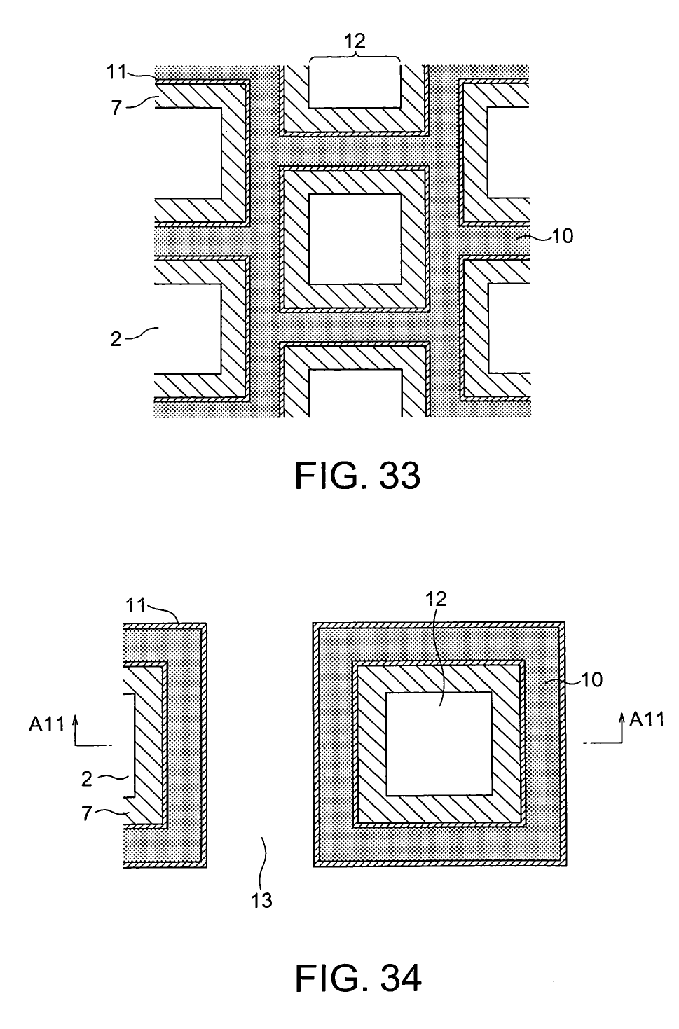

As shown in FIG. 33, an IGBT according to the first modification of the seventh embodiment of the present invention differs from the seventh embodiment described above in that trenches 9 are staggered into the shape of a lattice. This arrangement facilitates controlling the etching depth when the trenches 9 are formed, and makes element fabrication stable.

### EIGHTH EMBODIMENT

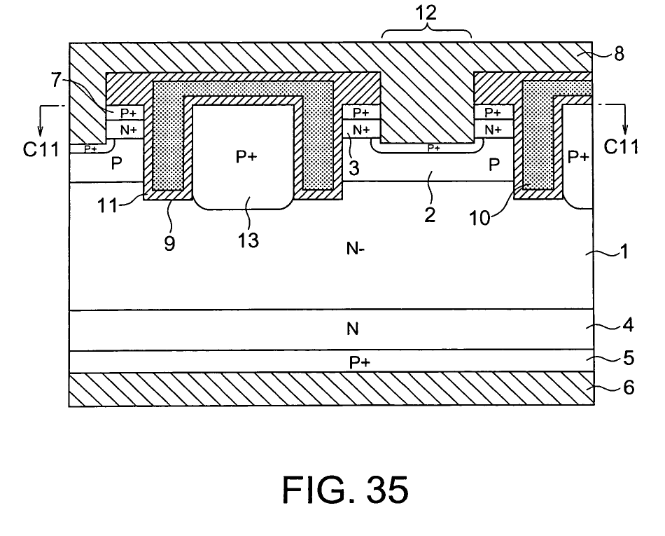

FIG. 34 shows the planar arrangement of an IGBT according to the eighth embodiment of the present invention. FIG. 35 shows a longitudinal section taken along a line A11-A11 in FIG. 34. The plan view of FIG. 34 corresponds to a cross section taken along a line C11-C11 in FIG. 35.

The IGBT of this embodiment differs from the seventh embodiment described above in that a trench 9 is formed into an annular shape, a current path including an n⁺-type emitter layer 3, p-type base layer 2, and p⁺-type limiting layer 7 is formed inside the trench 9, and a p⁺-type dummy layer 13 is formed outside the trench 9. With this arrangement, as in the second modification of the first embodiment described earlier, it is possible to suppress the rise of the ON-state voltage, and increase the short-circuit breakdown capability by suppressing the saturation current.

The above-mentioned embodiments are merely examples and do not limit the present invention. Therefore, these embodiments can be modified within the technical scope of the present invention.

1. A semiconductor device comprising:
a first-conductivity-type base layer;
a second-conductivity-type emitter layer formed on a first main surface of said first-conductivity-type base layer;
a collector electrode formed in contact with a surface of said second-conductivity-type emitter layer;
a second-conductivity-type base layer formed on a second main surface of said first-conductivity-type base layer;
a plurality of trenches which extend through said second-conductivity-type base layer to reach a predetermined depth of said first-conductivity-type base layer, and has a longitudinal direction in one direction;
a gate electrode formed in said trench via a gate insulating film;
a first-conductivity-type emitter layer selectively formed in contact with side walls of said trench, in a surface portion of said second-conductivity-type base layer;
an emitter electrode formed in contact with a surface of said second-conductivity-type base layer and a surface of said first-conductivity-type emitter layer; and
a second-conductivity-type semiconductor layer selectively formed in a region along the longitudinal direction of said trench, near the surface of said first-conductivity-type emitter layer.

2. A device according to claim 1, further comprising a first-conductivity-type barrier layer formed between said first-conductivity-type base layer and first-conductivity-type emitter layer.

3. A device according to claim 1, wherein
first and second regions are formed as regions surrounded by said trenches,
said first region has said first-conductivity-type emitter layer selectively formed in contact with the side walls of said trench, in the surface portion of said second-conductivity-type base layer, and said second-conductivity-type semiconductor layer selectively formed in the region along the longitudinal direction of said trench, near the surface of the first-conductivity-type emitter layer, and
said second region has a second-conductivity-type dummy layer.

4. A device according to claim 1, wherein in a surface portion of a region surrounded by said trenches, said second-conductivity-type semiconductor layer is formed in a region except for a portion where said first-conductivity-type emitter layer is in contact with said emitter electrode.

5. A device according to claim 1, wherein
said first-conductivity-type emitter layer has, in a surface portion of a region surrounded by said trenches, a first emitter region formed along the longitudinal direction of said trench, and a second emitter region formed along a direction perpendicular to the longitudinal direction of said trench, and
said second-conductivity-type semiconductor layer is formed at least on an intersection of said first and second emitter regions, in the surface portion of the region surrounded by said trenches.

6. A device according to claim 5, further comprising a second-conductivity-type semiconductor layer formed between said first emitter region of said first-conductivity-type emitter layer and said second-conductivity-type base layer.

7. A device according to claim 1, wherein
said first-conductivity-type emitter layer has, in a surface portion of a region surrounded by said trenches, a first emitter region formed along the longitudinal direction of said trench, and a second emitter region formed along a direction perpendicular to the longitudinal direction of said trench, and
said second-conductivity-type semiconductor layer is formed on said first emitter region except for an intersection of said first and second emitter regions, in the surface portion of the region surrounded by said trenches.

8. A device according to claim 1, wherein
said first-conductivity-type emitter layer has, in a surface portion of a region surrounded by said trenches, a first emitter region formed along the longitudinal direction of said trench, and a second emitter region formed along a direction perpendicular to the longitudinal direction of said trench, and
said second-conductivity-type semiconductor layer is formed into a shape of a stripe in the direction perpendicular to the longitudinal direction of said trench, except for an intersection of said first and second emitter regions, in the surface portion of the region surrounded by said trenches.

9. A device according to claim 1, wherein
said first-conductivity-type emitter layer has, in a surface portion of a region surrounded by said trenches, a plurality of first emitter regions formed along the longitudinal direction of said trench, and a plurality of second emitter regions formed along a direction perpendicular to the longitudinal direction of said trench, one end portion of each of said first emitter regions being connected to one of said second emitter regions, and the other end portion of each of said first emitter regions being separated from said second emitter regions, and
said second-conductivity-type semiconductor layer is formed on said first emitter region except for an intersection of said first and second emitter regions, in the surface portion of the region surrounded by said trenches.

10. A device according to claim 1, wherein
said first-conductivity-type emitter layer has, in a surface portion of a region surrounded by said trenches, a plurality of first emitter regions formed along the longitudinal direction of said trench, and a plurality of second emitter regions formed along a direction perpendicular to the longitudinal direction of said trench, a substantially central portion of each of said first emitter regions being connected to one of said second emitter regions, and two end portions of each of said first emitter regions being separated from other first emitter regions and said second emitter regions, and
said second-conductivity-type semiconductor layer is formed on said first emitter region except for an intersection of said first and second emitter regions, in the surface portion of the region surrounded by said trenches.

11. A semiconductor device comprising:
a first-conductivity-type base layer;
a second-conductivity-type emitter layer formed on a first main surface of said first-conductivity-type base layer;
a collector electrode formed in contact with a surface of said second-conductivity-type emitter layer;
a second-conductivity-type base layer formed on a second main surface of said first-conductivity-type base layer;
a plurality of trenches which extend through said second-conductivity-type base layer to reach a predetermined depth of said first-conductivity-type base layer;
a gate electrode formed in said trench via a gate insulating film;
a first-conductivity-type emitter layer selectively formed in contact with side walls of said trench, in a surface portion of said second-conductivity-type base layer;
an emitter electrode formed in contact with a surface of said second-conductivity-type base layer and a surface of said first-conductivity-type emitter layer; and
a second-conductivity-type semiconductor layer selectively formed in a region along a longitudinal direction of said trench, near the surface of said first-conductivity-type emitter layer,
wherein said trenches are formed into a mesh-like shape, and said gate electrode is formed into a mesh-like shape in said trench via said gate insulating film, and
in each region surrounded by said trenches,
said first-conductivity-type emitter layer is selectively formed along the side walls of said trench, in the surface portion of said second-conductivity-type base layer,
said emitter electrode is formed in contact with the surface of said second-conductivity-type base layer and the surface of said first-conductivity-type emitter layer, and
said second-conductivity-type semiconductor layer is selectively formed along the side walls of said trench, near the surface of said first-conductivity-type emitter layer.

12. A device according to claim 11, wherein in each region surrounded by said trenches,
said first-conductivity-type emitter layer is selectively formed along the side walls of said trench, in the surface portion of said second-conductivity-type base layer except for four corners,
said emitter electrode is formed in contact with the surface of said second-conductivity-type base layer and the surface of said first-conductivity-type emitter layer, and
said second-conductivity-type semiconductor layer is selectively formed along the side walls of said trench, near the surface of said first-conductivity-type emitter layer.

13. A device according to claim 11, wherein in each region surrounded by said trenches,
said emitter electrode is formed in contact with the surface of said second-conductivity-type base layer and the surface of said first-conductivity-type emitter layer, and
said second-conductivity-type semiconductor layer is selectively formed along the side walls of said trench, without being in contact with said emitter electrode, near the surface of said first-conductivity-type emitter layer.

14. A device according to claim 13, wherein a surface where said emitter electrode and first-conductivity-type emitter layer are in contact with each other is tapered with respect to said trench, thereby making an area of the contact surface larger than that when the contact surface is formed parallel to said trench.

15. A device according to claim 11, wherein in each region surrounded by said trenches,
a contact trench is formed in a region where said second-conductivity-type base layer and first-conductivity-type emitter layer are formed, and said emitter electrode is buried in said contact trench in contact with side surfaces of said second-conductivity-type base layer and side surfaces of said first-conductivity-type emitter layer on inner walls of said contact trench, and
said second-conductivity-type semiconductor layer is formed along the side walls of said trench and in contact with said emitter electrode on the inner walls of said trench, near the surface of said first-conductivity-type emitter layer.

16. A device according to claim 15, wherein said trenches are staggered into a shape of a lattice.

17. A semiconductor device comprising:
a first-conductivity-type base layer;
a second-conductivity-type emitter layer formed on a first main surface of said first-conductivity-type base layer;
a collector electrode formed in contact with a surface of said second-conductivity-type emitter layer;
a second-conductivity-type base layer formed on a second main surface of said first-conductivity-type base layer;
a plurality of trenches which extend through said second-conductivity-type base layer to reach a predetermined depth of said first-conductivity-type base layer;
a gate electrode formed in said trench via a gate insulating film;
a first-conductivity-type emitter layer selectively formed in contact with side walls of said trench, in a surface portion of said second-conductivity-type base layer;
an emitter electrode formed in contact with a surface of said second-conductivity-type base layer and a surface of said first-conductivity-type emitter layer; and
a second-conductivity-type semiconductor layer selectively formed in a region along a longitudinal direction of said trench, near the surface of said first-conductivity-type emitter layer,
wherein said plurality of trenches are formed into an annular shape, and said gate electrode is buried in said trench via said gate insulating film, and
in each region surrounded by said annular trenches,
said first-conductivity-type emitter layer is selectively formed along the side walls of said trench, in the surface portion of said second-conductivity-type base layer,
said emitter electrode is formed in contact with the surface of said second-conductivity-type base layer and the surface of said first-conductivity-type emitter layer, and
said second-conductivity-type semiconductor layer is selectively formed along the side walls of said trench, near the surface of said first-conductivity-type emitter layer.
